(19) United States
(12) Patent Application Publication
(10) Pub. No.: US 2013/0141178 A1
(43) Pub. Date: Jun. 6, 2013

(54) Injection Locked Divider with Injection Point Located at a Tapped Inductor

(71) Applicant: Zaw Soe, Encinitas, CA (US)

(72) Inventor: Zaw Soe, Encinitas, CA (US)

(73) Assignee: Tensorcom, Inc, Carlsbad, CA (US)

(21) Appl. No.: 13/312,820

(22) Filed: Dec. 6, 2011

(51) Int. Cl. H03B 5/12

(52) U.S. Cl. 331/117 FE

(57) ABSTRACT

Injection locked dividers provide a divided clock signal after being driven by a injected clock signal that is a multiple of the divided clock signal. At injected clock signal at 60 GHz generates a differential 30 GHz clock signal. One innovative construction of the injection locked oscillator reduces the internal capacitive at a node by associating the parasitic capacitance at this node with the inductors of the tapped inductor resonant circuit. This provides more energy flow in the injection pulses applied to the legs of the injection locked circuit providing an increase locking range.

### CROSS REFERENCE TO RELATED APPLICATIONS

The present application is related to the co-filed U.S. application entitled “Method and Apparatus of an Input Resistance of a Passive Mixer to Broaden the Input Matching Bandwidth of a Common Source or Common Gate LNA” both filed on Dec. 6, 2011, which are invented by the same inventor as the present application and incorporated herein by reference in their entireties.

### BACKGROUND OF THE INVENTION

The Federal Communications Commission (FCC) has allotted a spectrum of bandwidth in the 60 GHz frequency range (57 to 64 GHz). The Wireless Gigabit Alliance (WiGig) is targeting the standardization of this frequency band that will support data transmission rates up to 7 Gbps. Integrated circuits, formed in semiconductor die, offer high frequency operation in this millimeter wavelength range of frequencies. Some of these integrated circuits utilize Complementary Metal Oxide Semiconductor (CMOS), Silicon-Germanium (SiGe) or GaAs (Gallium Arsenide) technology to form the dice in these designs. At 60 GHz, a divider of a clock signal providing a 30 GHz is an important building block. Another important consideration is locking or synching the on-chip oscillator to a second independent clock signal.

CMOS (Complementary Metal Oxide Semiconductor) is the primary technology used to construct integrated circuits. N-channel devices and P-channel devices (MOS device) are used in this technology which uses fine line technology to consistently reduce the channel length of the MOS devices. Current channel lengths are 40 nm, the power supply of VDD equals 1.2V and the number of layers of metal levels can be 8 or more.

Oscillator and frequency dividers are elements in communication systems. The highest performance circuits in a given technology are usually measured in some form of an on-chip free running oscillator, such as a ring oscillator using transistors or a resonant oscillator that uses transistors and reactive components in a regenerative connection. Once these clocks are generated on-chip, a Phase Lock Loop (PLL) can be used to control the frequency of operation as is well known in the art.

Another method of adjusting the frequency of operation of on-chip oscillator is by injecting a second independent clock signal into the clock circuit. This second independent clock signal can be used to lock and maintain the frequency of operation of the free running oscillator within tight bounds. An injection locked on-chip oscillator has a range of frequencies that the oscillator will lock on to (the locking range). In addition, the output of the oscillator can generate a divide-by-two frequency output that is locked to the higher frequency injection signal.

High frequency signals as used in WiGig transceivers have carrier frequencies around 60 GHz. Parasitic capacitance plays an influential role the performance of electrical circuits. The drain/gate capacitive is about 10 fF per micron width. In particular, this parasitic capacitance can degrade the operation of on-chip clock oscillators, which are typically the components on a chip that achieve the highest frequency capabilities.

### BRIEF SUMMARY OF THE INVENTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

One of the embodiments of the disclosure reduces the parasitic drain capacitance at an internal node in an on-chip injection locked divider oscillator. The reduction is achieved by associating the parasitic capacitances on the drain node with the inductors of the tapped inductor resonant circuit. This parasitic capacitance becomes part of the resonant circuit of the oscillator reducing energy loss. This allows the on-chip oscillator to exceed the WiGig frequencies requirements where the higher frequencies achieved by the divider can be traded by reducing the frequency (and making the WiGig requirement) or improving the linearity of the clock signal.

Another embodiment uses the injection signal to lock the output of the on-chip oscillator to generate an output clock signal that is divided or a sub-harmonic frequency and thereby eliminating the requirement of separate computation unit to create the divided down clock signal.

### BRIEF DESCRIPTION OF THE DRAWINGS

Please note that the drawings shown in this specification may not necessarily be drawn to scale and the relative dimensions of various elements in the diagrams are depicted schematically. The inventions presented here may be embodied in many different forms and should not be construed as limited to the embodiments set forth herein. Rather, these embodiments are provided so that this disclosure will be through and complete, and will fully convey the scope of the invention to those skilled in the art. In other instances, well-known structures and functions have not been shown or described in detail to avoid unnecessarily obscuring the description of the embodiment of the invention. Like numbers refer to like elements in the diagrams.

FIG. 1a depicts two oscillators on a die where one oscillator can injection lock to a second oscillator.

FIG. 1b shows an external signal from a first oscillator injection locking an oscillator.

FIG. 2 graphs a plot of the locking range of an injection locked oscillator.

FIG. 3 illustrates a conventional phase look loop.

FIG. 4a presents an injection locked oscillator introducing stimulus at a device node in accordance with the present invention.

FIG. 4b depicts a block diagram of FIG. 4a in accordance with the present invention.

FIG. 5a shows an injection locked oscillator introducing stimulus at a tapped inductor node in accordance with the present invention.

FIG. 5b illustrates a block diagram of FIG. 5a in accordance with the present invention.

FIG. 6a depicts a simplified version after removing the frequency control circuit of FIG. 4a in accordance with the present invention.

FIG. 6b illustrates a block diagram of FIG. 6a in accordance with the present invention.

FIG. 7a depicts a simplified version after removing the frequency control circuit of FIG. 5a in accordance with the present invention.

FIG. 7b shows a block diagram of FIG. 7a in accordance with the present invention.

### DETAILED DESCRIPTION OF THE INVENTION

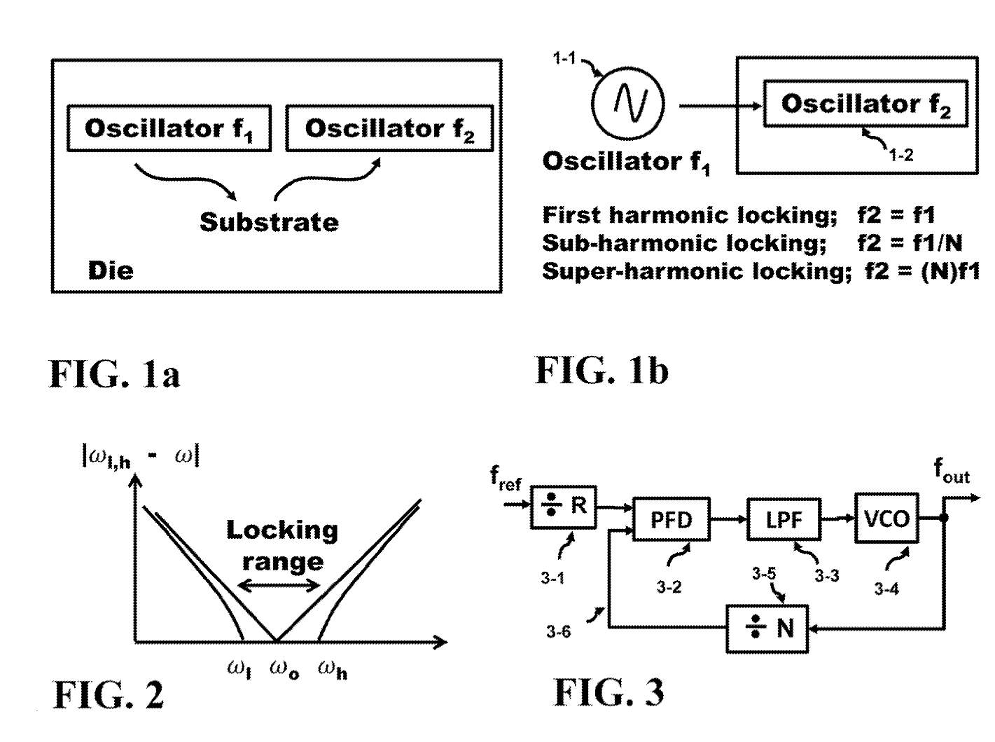

FIG. 1a illustrates an on-chip oscillator operating at a frequency of f₁ and a second on-chip oscillator operating at a frequency of f₂ on the same die. Assume for the moment that these oscillators are resonant oscillators. A resonant oscillator or circuit comprises at least one inductor and at least one capacitor. The inductors can have a parasitic capacitance, a static capacitance, and possibly a controlled capacitance (electrically) and together with said inductors form a resonant circuit. The substrate of the die couples the signal from the first oscillator to the second oscillator. If the two frequencies are within the locking range of each other, the frequencies of the two oscillators will become locked and synchronized, thereby operating at the same or multiple frequencies of each other.

Depending on the system requirement, this feature of being locked in frequency between two on-chip oscillators may or may not be desirable. If the intent is undesirable, then the locking of the two oscillators can cause system failure. For example, an on-chip oscillator at one corner of the chip can lock with another supposedly independent on-chip oscillator at a different area or section of the chip. The frequency shift of the second independent on-chip oscillator may cause this section of the chip to generate errors.

The three categories of locking in a free running oscillator are presented in FIG. 1b. A clock 1-1 operating at f₁ is applied to a free running oscillator 1-2 operating at a first frequency of f₂. The on-chip oscillator 1-2 can be either locked to the first harmonic (f₂=f₁), locked sub-harmonically f₂ (f₁)/N, or locked super-harmonically f₂=(N)(f₁).

The highest clock signal in WiGig has such a short duration (16 ps) at 60 GHz and would require a resonant oscillator to create this frequency in CMOS. The delay through the 40 nm MOS device is about the shortest delay that can be achieved in this technology for a single device. Any computational unit being clocked by this signal such as a divider formed using conventional CMOS gates (NAND, NOR, FF, etc.) formed of several devices would typically fail since the required duration is longer than 16 ps. However, for a custom designed computational block (See patent application Ser. No. 13/243,908 “A High Performance Divider Using Feed Forward, Clock Amplification and Series Peaking Inductors” filed on Sep. 23, 2011 by the same inventor as this application), inventive techniques can be incorporated into a custom design to create custom CMOS gates that operate within the 16 psec period.

For an injection locked divider, the highest generated clock signal in WiGig has a longer duration (32 ps) since the divider is operating at 30 GHz while the external injected signal is operating at 60 GHz. This alleviates the critical issue of dividing a free running oscillator operating at 60 GHz clock signal with a specialized divider circuit.

The locking range for the first harmonic is illustrated in FIG. 2. The locking range is defined and ranges from ω₁ to ωₕ. If the external clock signal lies within this range, the free running oscillator locks to the stimulus frequency; otherwise, the oscillator fails to lock. The free running oscillator also opens the locking range to any other undesirable dominant stimulus that may be created on-chip within this frequency range to upset the initial desired intent of locking to the second clock signal. If the undesired signal is captured by the free running oscillator in place of the second clock signal, then the oscillator may not lock as initially desired.

FIG. 3 illustrates a conventional PLL. The reference external frequency of f_{ref} is divided down by R in block 3-1. The low frequency signal is compared in the PDF (Phase and Frequency Detector) 3-2 against the clock signal 3-6. The VCO 3-4 generates the high frequency signal fₒᵤₜ. This signal is presented to the prescalar 3-5 and is divided by N and compared against a reference signal in the PFD block 3-2. The output of the PFD is low pass filtered (LPF 3-3) to generate a DC voltage that is applied to the VCO to adjust the high frequency signal fₒᵤₜ. Another layer of frequency control is inserted into the free running oscillator by inserting the PLL between the free running oscillator and the second clock input signal f_{ref}. The PLL can provide a control to adjust the frequency of the clock.

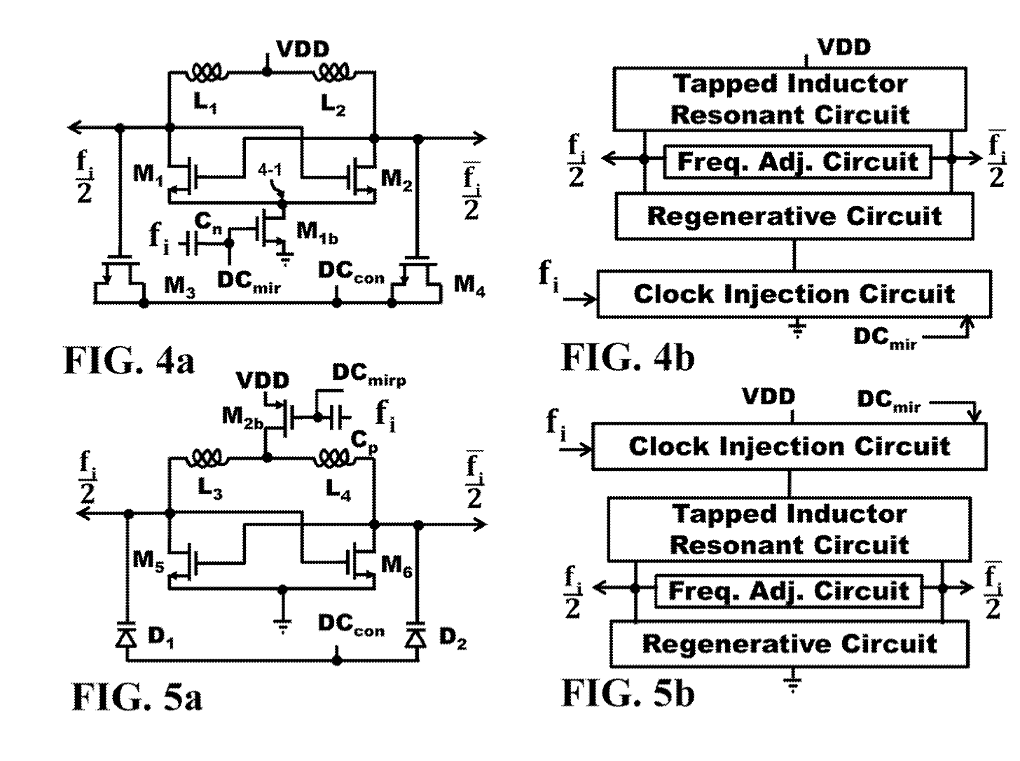

FIG. 4a shows an injection sub-harmonic locked oscillator. The injected clock signal is f₁ and is coupled to the gate of M_{1b} via the coupling capacitor Cₙ. The device M_{1b} sets the bias current of the oscillator circuit which can be controlled by a mirror voltage DCₘᵢᵣ developed in a current mirror circuit (not fully shown), by a resistive divider, by a constant voltage, or by other control means. The clock injection circuit comprises the capacitor Cₙ and the N-channel device M_{1b}. The voltage DCₘᵢᵣ and the input signal fᵢ are applied to the clock injection circuit. The clocked device M_{1b} introduces current spikes into the resonant circuit to synchronize the injection locked oscillator.

The inductor is tapped midway between its ends partitioning the inductor into two inductors: L₁ and L₂. The tapped midway point is coupled to VDD as illustrated. The capacitive load (not fully illustrated) exists on the output node and consists of a parasitic component, a component due to the load and an adjustable component (varactor). The capacitive component comprises the capacitance of the drain of M₁ and the gate of M₂, the capacitance of the interconnect, the capacitance of the output load on the output node, and the capacitance of M₃ controlled by the voltage DC_{con}. The capacitive load, the two inductors and any resistive loss forms the resonant RLC circuit. This resonant RLC circuit oscillates at fᵢ/2. The left leg of the resonant circuit comprises the inductor L₁ and the drain to source path in the device M₁. Similarly, the capacitive load on the output node generating f̅₁̅/̅2̅ comprises the capacitance of the drain of M₂ and the gate of M₁, the capacitance of the interconnect, the capacitance of the output load on the output node, and the capacitance of M₄ controlled by the voltage DC_{con}. The capacitance of M₃ and M₄ can be an MOS devices biased by DC_{con} to be either in the accumulation, depletion or inversion mode. The right leg of the resonant circuit comprises the inductor L₂ and the drain to source path in the device M₂. The natural frequency of the oscillator is controlled by the capacitive load and the inductors. A resistive loss (not shown) is due to the resistance of the metal traces forming the inductor, as well as, the resistive and dielectric losses of the capacitors. The lapped inductor resonant circuit comprises the capacitive load, the inductors and the resistive loss. The circuit has three nodes; the single tapped node common to the two inductors L₁ and L₂ and the left and right output nodes at the opposing ends of these two inductors. An equal capacitive load is coupled to each of these two output nodes.

An adjustable capacitance value is provided by the devices M₃, M₄ and the control voltage DC_{con}. The voltage DC_{con} is adjusted until the capacitance value added to the circuit causes the free running oscillator to operate within the locking range of the oscillator. The capacitance presented to the output nodes varies as the voltage DC_{con} is adjusted to vary the frequency of the resonant circuit. The frequency adjust circuit comprises the device M₃, device M₄, and the common node connecting both the drain and source of the devices M₃ and M₄ together. The voltage DC_{con} is applied to this common node and is used to adjust the capacitive load.

A cross-coupled structure comprising devices M₁ and M₂ is also shown in FIG. 4a.The drain of device M₁ couples to the gate of device M₂ while the drain of device M₂ is coupled to the gate of device M₁. These two devices provide a negative impedance that compensates for any resistive loss in the resonant circuit. The drain of the first device generates a clock operating at fᵢ/2 while the drain of the other device generates a clock operating at f̅₁̅/̅2̅ . The sources of the first and second devices are connected together as a single node. The regenerative circuit comprises the devices M₁ and M₂ and their cross-coupling network. The regenerative circuit has a left and right drain nodes coupled to the drain of devices M₁ and M₂ while a common node connects the source of the two devices.

The oscillator is injection locked to half the frequency of fᵢ by the injected signal fᵢ where the divider generates a clock frequency operating at f₁/2. The injected signal increases the current spike in the device M_{1b} once per fᵢ cycle. The device M_{1b} is a current source but does not have infinite impedance; thus, the output resistance of M_{1b} interacts with node 4-1 to create a time constant related to the output impedance of the device and the capacitive load at node 4-1. Each alternate current spike flows through the same leg of the resonant circuit providing energy pulses to the resonant circuit. The first current spike flows through the left leg, the second current spike flows through the right leg, the third current spike flows through the left leg, . . . thus causing the resonant circuit to oscillate at half of the frequency.

FIG. 4b provides a block diagram of the circuit illustrating how the circuits are coupled together in FIG. 4a. The power supply voltage VDD is applied to the single tapped node of the inductor in the tapped inductor resonant circuit. Each of the left and right output nodes of the tapped inductor resonant circuit couple to a capacitor to form the RLC resonant circuit that provides the two output clock signals f̅₁̅/̅2̅ and fᵢ/2. The left and right output nodes of the tapped inductor resonant circuit couple to the left and right drain nodes of the cross-coupled devices of the regenerative circuit. The frequency adjust circuit is coupled to the two output clock signals f̅₁̅/̅2̅ and fᵢ/2 and is adjusted by a voltage DC_{con}. The single node of the regenerative circuit is connected to the clock injection circuit which is clocked by fᵢ. The signal DCₘᵢᵣ adjusts the current of the resonant circuit. The clock injection circuit is further connected to ground via the common node.

One embodiment depicting the invention of an injection sub-harmonic locked oscillator is shown in FIG. 5a. The injection clock signal is fᵢ and is coupled to the gate of P-channel device M_{2b} via the coupling capacitor Cₚ. The device M_{2b} sets the bias current of the oscillator circuit which can be controlled by a mirror voltage DCₘᵢᵣₚ developed in a current mirror circuit (not fully shown), by a resistive divider, by a constant voltage, or by other control means. Another embodiment of the clock injection circuit comprises the capacitor Cₚ and the P-channel device M_{2b}. The voltage DCₘᵢᵣₚ and the input signal are applied to this circuit. The capacitive control uses the varactors D₁ and D₂ which operate at a threshold voltage of zero volts to help compensate for the voltage drop loss of the P-channel clock injection circuit. Varactors are required to compensate for the reduced headroom in the circuit of FIG. 5a because the device M_{2b} drops the operating voltage to the cross-coupled oscillator. Thus, the MOS devices in FIG. 4a are replaced by varactors D₁ and D₂ in the circuit of FIG. 5a. Varactors can present a capacitive load yet only require a “0V” threshold to operate.

In FIG. 5a, the inductor is tapped midway between its ends partitioning the tapped inductor into L₃ and L₄. The single tapped node is coupled to drain of the device M_{2b} as illustrated. The capacitive load (not shown) on the output node of fᵢ/2 comprises the capacitance of the cathode of D, and the gate of M₆, the capacitance of the interconnect, the capacitance of the output load on the output node, and the capacitance of D₁ controlled by the voltage DC_{con}. The left leg of the resonant circuit comprises the inductor L₃ and the drain to source path in the device M₅. Similarly, the capacitive load on the output node of f̅₁̅/̅2̅ comprises the capacitance of the drain of M₆, the cathode of D₂, the capacitance of the interconnect, the capacitance of the output load on the output node of f̅₁̅/̅2̅ and the capacitance of D₂ controlled by the voltage DC_{con}. The right leg of the resonant circuit comprises the inductor L₄ and the drain to source path in the device M₆. The natural frequency of the oscillator is controlled by the capacitive load and the inductors. A resistive loss is due to the resistance of the metal traces forming the inductor, as well as, the resistive and dielectric losses of the capacitors. The tapped inductor resonant circuit comprises the capacitive load, the two tapped inductors and any resistive loss of the components.

The voltage DC_{con} is adjusted until the capacitance value causes the free running oscillator to operate within the locking range of the oscillator. The adjustable capacitance value is provided by the varactors D₁, D₂ and the control voltage DC_{con}. As the voltage DC_{con} is adjusted, the capacitance presented to the output nodes varies allowing frequency control of the resonant circuit. Another embodiment of the frequency adjust circuit comprises the varactor D₁, varactor D₂, and the common node connecting the anodes of the devices D₁ and D₂. The voltage DC_{con} is applied to this circuit.

A cross-coupled structure comprising devices M₅ and M₆ is also shown in FIG. 5a.The drain of device M₅ couples to the gate of device M₆ while the drain of device M₆ is coupled to the gate of device M₅. The drains of the two devices are each coupled to one of the two outputs while their sources are connected together as a common node coupled to ground. Another embodiment of the regenerative circuit comprises the devices M₅ and M₆.

The oscillator is injection locked by the injected signal fᵢ and locks the oscillator to operate at a frequency fᵢ/2. The injected signal increases the current (current spike) in the device M_{2b} once per fᵢ cycle. Each alternate current spike flows through the same leg of the resonant circuit. The first current spike flows through the left leg, the second current spike flows through the right leg, the third current spike flows through the left leg, . . . thus causing the resonant circuit to oscillate at half of the frequency.

FIG. 5b provides a block diagram of the circuit illustrating how the circuits are coupled together in FIG. 5a. The power supply voltage VDD is applied to the source of P-channel device M_{2b} in the clock injection circuit while the drain output of device M_{2b} is connected to the single tapped node of the tapped inductor resonant circuit. The left and right output nodes of the tapped inductor resonant circuit are then connected to the left and right drain nodes of the regenerative circuit. The frequency adjust circuit is coupled to the two clock outputs which provide the output clock signals f̅₁̅/̅2̅ and fᵢ/2. The regenerative circuit is further connected to ground via the common node.

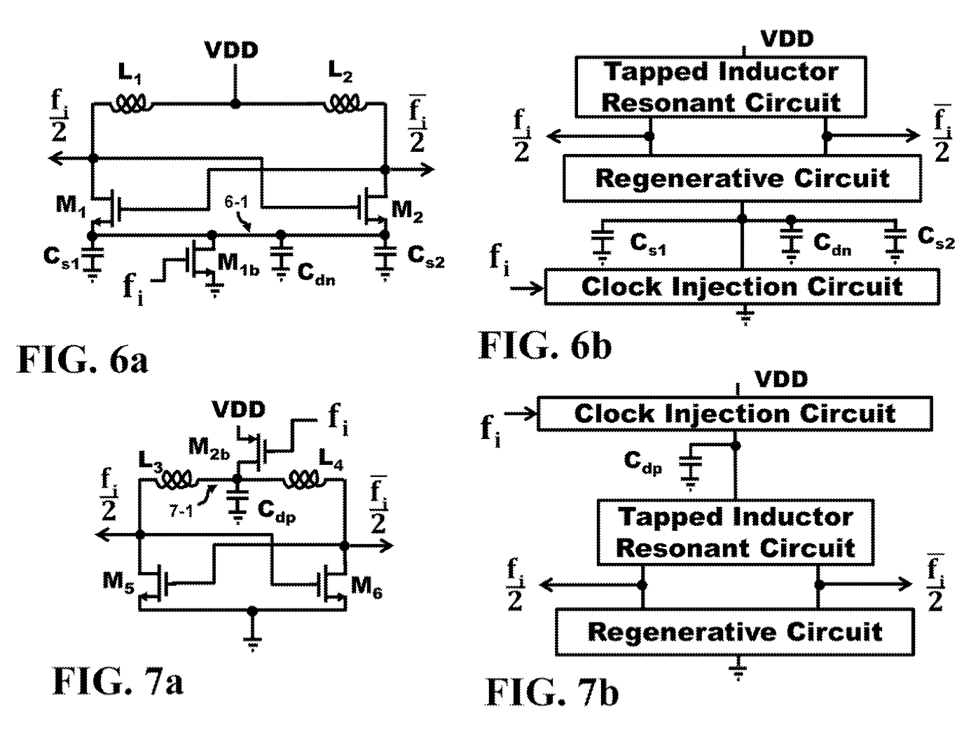

FIG. 6a and FIG. 7a provides a version of the circuit illustrated in FIG. 4a and FIG. 5a, respectively, by removing the frequency adjust circuit. This simplifies the diagram and allows an easier comparison between the two circuits.

In FIG. 6a, similar marked components as given in FIG. 4a are equivalent. The additional components includes the capacitors; Cₛ₁, Cₛ₂ and C_{dn} which share the merged node 6-1 between the coupled devices M₁, M₂ and M_{1b}. The capacitor Cₛ₁ corresponds to the source capacitance of device M₁, the capacitor Cₛ₂ corresponds to the source capacitance of device M₂, and capacitor C_{dn} corresponds to the drain capacitance of device M_{1b}. The total capacitance at node 6-1 is the summation of the three parallel capacitors Cₛ₁+Cₛ₁+C_{dn}. Note that the two devices M₁ and M₂ isolate these capacitors from the tapped inductor resonant circuit; thus, these capacitors cannot be associated with the resonant circuit. The current source of device M_{1b} has finite impedance and a finite turn on time. In addition, the total capacitance at node 6-1 causes the current spike to decrease the energy flow of the pulses flowing through the left and right legs of the tapped inductor resonant circuit. Thus, this reduction of energy pulses can decrease the locking range of the injection locked oscillator from the ideal case. FIG. 6b provides the block diagram representation of the circuit provided in FIG. 6a.

In FIG. 7a, similar marked components as given in FIG. 5a are equivalent. The additional component includes the single capacitor; C_{dp} which corresponds to the drain of M_{2b}. This capacitance is on the merged node 7-1 between device M_{2b} and the single tapped node between the two inductors L₃ and L₄. The reactive component of the capacitance can be associated with the two inductors in the tapped inductor resonant circuit; thus, C_{dp} resonates with the inductors to become part of the resonant circuit. The capacitor C_{dp} corresponds to the drain capacitance of device M_{2b}; thus, the total capacitance at node 7-1 is the capacitance C_{dp} and this capacitance can be absorbed as part of the resonant circuit. Because the capacitance at node 7-1 has been reduced or absorbed into the resonant circuit, and although the current source of device M_{1b} has a finite impedance and a finite turn on time, the current spike increases the energy pulses flowing through the left and right legs of the tapped inductor resonant circuit when compared to the case illustrated in FIG. 6a. Thus, this increase of energy flow in the pulses can improve the locking range of the injection locked oscillator over that of the oscillator provided in FIG. 6a. FIG. 7b provides the block diagram representation of the circuit provided in FIG. 7a

Finally, it is understood that the above description are only illustrative of the principle of the current invention. Various alterations, improvements, and modifications will occur and are intended to be suggested hereby, and are within the spirit and scope of the invention. This invention may, however, be embodied in many different forms and should not be construed as limited to the embodiments set forth herein. Rather, these embodiments are provided so that the disclosure will be thorough and complete, and will fully convey the scope of the invention to those skilled in the arts. It is understood that the various embodiments of the invention, although different, are not mutually exclusive. In accordance with these principles, those skilled in the art may devise numerous modifications without departing from the spirit and scope of the invention. Although the circuits were described using CMOS, the same circuit techniques can be applied to depletion mode devices and BJT or bipolar circuits, since this technology allows the formation of current sources and source followers. When a device is specified, the device can be a transistor such as an N-MOS or P-MOS. The CMOS or SOI (Silicon on Insulator) technology provides two enhancement mode channel types: N-MOS (N-channel) and P-MOS (P-channel) devices or transistors.

What is claimed is:

1. An injection locked oscillator comprising:
an injected clock signal operating at a first frequency;
a clock injection circuit driven by the injected clock signal;
the clock injection circuit generates current spikes at the first frequency;
a tapped inductor resonant circuit coupled to a regenerative circuit;
the tapped inductor resonant circuit routes each alternate current spike to a first leg of the oscillator; and
the tapped inductor resonant circuit routes each remaining current spike to a second leg of the oscillator.

2. The oscillator of claim 1, whereby
a clock output is available at a node in the first leg between the tapped inductor resonant circuit and the regenerative circuit.

3. The oscillator of claim 2, whereby
an inverse clock output is available at a node in the second leg between the tapped inductor resonant circuit and the regenerative circuit.

4. The oscillator of claim 3, whereby
the clock and the inverse clock outputs operates in a locked mode selected from the group consisting of sub-harmonic, first harmonic and super-harmonic.

5. The oscillator of claim 3, further comprising:
a cathode of a first varactor coupled to the clock output;
a cathode of a second varactor coupled to the inverse clock output; and
anodes of the first and second varactors coupled to a second DC voltage bias.

6. The oscillator of claim 5, whereby
the second DC voltage bias is varied to adjust a capacitance of the first and second varactor coupled to the clock outputs.

7. The oscillator of claim 3, further comprising:
a gate of a first MOS device coupled to the clock output;
a gate of a second MOS device coupled to the inverse clock output; and
drains and sources of the first and second MOS devices coupled to a first DC voltage bias.

8. The oscillator of claim 7, whereby
the first DC voltage bias is varied to adjust gate capacitance of the first and second MOS device coupled to the clock outputs.

9. A method of operating an injection locked oscillator comprising the steps of:
applying an injected clock signal to a clock injection circuit with a locking range;
coupling a first node of the clock injection circuit to a single tapped node of a tapped inductor resonant circuit;
coupling a left and a right output node of the tapped inductor resonant circuit to a left and a right drain node of a regenerative circuit, respectively;
associating all parasitic capacitances on the single tapped node with inductors of the tapped inductor resonant circuit, and
locking the frequency of operation of the injection locked oscillator if the injected clock signal is within the locking range.

10. The method of claim 9, whereby
a clock output is available at a node in the first leg between the tapped inductor resonant circuit and the regenerative circuit.

11. The method of claim 10, whereby
an inverse clock output is available at a node in the second leg between the tapped inductor resonant circuit and the regenerative circuit.

12. The method of claim 11, whereby
the clock and the inverse clock outputs operates in a locked mode selected from the group consisting of sub-harmonic, first harmonic and super-harmonic.

13. The method of claim 11, further comprising the steps of:
coupling a cathode of a first varactor to the clock output;
coupling a cathode of a second varactor to the inverse clock output; and
coupling anodes of the first and second varactors to a second DC voltage bias.

14. The method of claim 13, whereby
the second DC voltage bias is varied to adjust a capacitance of the first and second varactor coupled to the clock outputs.

15. The method of claim 9, whereby
the association of the parasitic capacitance with the resonant circuit improves the locking range.

16. A method of operating a injection locked oscillator comprising the steps of:
operating an injected clock signal at a first frequency;
driving a clock injection circuit by the injected clock signal;
generating current spikes by the clock injection circuit at the first frequency;
coupling a tapped inductor resonant circuit to a regenerative circuit;
routing each alternate current spike to a first leg of the injection locked oscillator; and
routing each remaining current spike to a second leg of the injection locked oscillator, thereby
locking the injection locked oscillator.

17. The method of claim 16, whereby
a clock output is available at a node in the first leg between the tapped inductor resonant circuit and the regenerative circuit.

18. The method of claim 17, whereby
an inverse clock output is available at a node in the second leg between the tapped inductor resonant circuit and the regenerative circuit.

19. The method of claim 18, whereby
the clock and the inverse clock outputs operates in a locked mode selected from the group consisting of sub-harmonic, first harmonic and super-harmonic.

20. The method of claim 16, further comprising the steps of:
coupling a cathode of a first varactor to the clock output;
coupling a cathode of a second varactor to the inverse clock output; and
coupling anodes of the first and second varactors to a second DC voltage bias.
